(19) United States
(12) Patent Application Publication
(10) Pub. No.: US 2006/0244088 A1
(43) Pub. Date: Nov. 2, 2006

(54) Solid-state image pick-up device

(76) Inventors: Makoto Inagaki, Kyoto (JP); Kazuaki Igaki, (US); Kosaku Saeki, (US)

Correspondence Address: MCDERMOTT WILL & EMERY LLP, 600 13TH STREET, N.W., WASHINGTON, DC, 20005-3096, US

(21) Appl. No.: 11/390,246

(22) Filed: Mar. 28, 2006

(30) Foreign Application Priority Data
Mar. 28, 2005 (JP) 2005-092865

(51) Int. Cl. H01L 31/00

(52) U.S. Cl. 257/451

(57) ABSTRACT

A MOS solid-state image pick-up device with a high S/N ratio is provided. On a surface of a photo-detecting section 2 formed inside a semiconductor substrate, an antireflection film 10 having a smaller area than a surface area of the photo-detecting section 2, with an insulating film 6 imposed therebetween, is provided. The antireflection film 10 is formed so as not to cover bordering portions between the photo-detecting section 2 and peripheral regions thereof. Each of a distance of a clearance S1 between the antireflection film 10 and a gate electrode 7 and a distance of a clearance between the antireflection film 10 and an element isolation region 5 is preferably equal to or greater than 0.2 μm. When the area of the antireflection film 10 is equal to or greater than 70% of the surface area of the photo-detecting section 2, even if used for a camera with interchangeable lenses, a fluctuation in sensitivity among pixels can be suppressed.

### BACKGROUND OF THE INVENTION

1. Field of the Invention

The present invention relates to a MOS solid-state image pick-up device.

2. Description of the Background Art

Conventionally, as a solid-state image pick-up device, a CCD (Charge Coupled Device) solid-state image pick-up device and a MOS solid-state image pick-up device have been known. The CCD solid-state image pick-up device has an advantage of attaining a high S/N ratio because of high sensitivity and low dark output. Owing to this advantage, the CCD solid-state image pick-up device has conventionally dominated camera markets. However, the CCD solid-state image pick-up device has a disadvantage of taking a long time for reading out an image signal due to a structure thereof in which a signal electric charge accumulated in a photo-detecting section of a pixel is transferred to a final output section by means of a vertical CCD and a horizontal CCD in a sequential manner and thereafter converted to an electrical signal.

FIG. 8A and FIG. 8B show an example of a conventional MOS solid-state image pick-up device. FIG. 8A is a top view of a pixel section and FIG. 8B is a cross-sectional view of the pixel section along a line A-B. Within a semiconductor substrate 101 which is a P-type silicon substrate, the pixel section comprises an N⁻-type photo-detecting section 102, a P⁺⁺-type surface layer 103, an N⁺-type drain region 104, an isolation region 105, and an N-type LDD (Light Doped Drain) section 108. On a surface of the semiconductor substrate 101, an insulating film 106 which is a silicon oxide film is formed. On the insulating film 106, a gate electrode 107, a sidewall 109 of a silicon oxide, an interlayer dielectric film 111, a light-shielding film 112 and the like are formed. A transfer transistor comprises a part of a photo-detecting section 102, apart of the semiconductor substrate 101, a drain region 104, and a gate electrode 107. Though not shown, on the light-shielding film 112, an interlayer dielectric film, a color filter, a microlens and the like are formed. An electric charge accumulated in the photo-detecting section 102 runs through a channel which appears on the surface of the semiconductor substrate 101 upon an application of a predetermined voltage to the gate electrode 107 and is transferred to the drain region 104.

FIG. 9 shows an example of a circuit in the pixel section. The drain region 104 of a transfer transistor is connected to readout circuits such as an amplifying transistor 118 and a reset transistor 119. On a vertical signal line VSL, a signal in accordance with a quantity of the electric charge transferred to the drain region 104 from the photo-detecting section 102 appears and is read out to a final output section. Because the MOS solid-state image pick-up device does not comprise charge transfer sections such as the vertical CCD and the horizontal CCD, the MOS solid-state image pick-up device has an advantage in that the MOS solid-state image pick-up device takes a shorter time to read out an image than the CCD solid-state image pick-up device comprising the charge transfer sections takes.

For manufacturing the conventional MOS solid-state image pick-up device, however, since a CMOS logic process is used without any modification, adequate measures for improving sensitivity and reducing the dark output are not taken, resulting in a low S/N ratio. Accordingly, a challenge in the manufacturing the MOS solid-state image pick-up device is to improve the S/N ratio.

As a technique for improving the S/N ratio, as shown in the solid-state image pick-up device in FIG. 10, providing an antireflection film 110 so as to cover an entire surface of the photo-detecting section 102 had been proposed (for example, refer to Japanese Laid-Open Patent Publication No. 10-256610). It had been considered that providing the antireflection film 110 would allow a reduction in reflection, which is caused by a difference in refractive indices of the insulating film 106 and the semiconductor substrate 101, on a surface of the photo-detecting section 102 and thereby would attain a high S/N ratio.

In reality, however, it has been found that even increasing a quantity of light received, through providing the antireflection film 110 on the entire surface of the photo-detecting section 102, does not lead to attaining a desired S/N ratio.

### SUMMARY OF THE INVENTION

Therefore, an object of the present invention is to provide a MOS solid-state image pick-up device which is capable of attaining a high S/N ratio.

A solid-state image pick-up device comprises a plurality of pixels arranged on a semiconductor substrate, each of the pixels each including a photo-detecting section for accumulating an electric charge in accordance with a quantity of light received; a plurality of antireflection films, each having an area smaller than a surface area of the photo-detecting section and formed on each of the photo-detecting sections; and an interlayer dielectric film having a plurality of openings, each having an area equal to or greater than the surface area of the photo-detecting section, which are formed above the antireflection film.

The solid-state image pick-up device further comprises an isolation region for isolating the pixels from each other, wherein a clearance between the isolation region and the antireflection film is equal to or greater than 0.2 μm.

The solid-state image pick-up device further comprises a plurality of transfer transistors, the transfer transistors each being adjacent to the photo-detecting section, wherein a clearance between the gate electrode of the transfer transistor and the antireflection film is equal to or greater than 0.2 μm.

In the MOS solid-state image pick-up device, an area of the antireflection film is equal to or greater than 70% of the surface area of the photo-detecting section.

In the solid-state image pick-up device according to the present invention, the antireflection film is formed not around boundaries between the photo-detecting section and the gate electrode and not around boundaries between the photo-detecting section and the element isolation region, and has a smaller area than the surface area of the photo-detecting section. Through forming the antireflection film in the above-mentioned manner, an increase in a number of surface defects of the semiconductor substrate can be suppressed and thereby an increase in dark output can also be suppressed.

A microlens is, in general, provided above a photo-detecting region and light collected by a collective lens is collected into the photo-detecting region in a pinpointed manner. Therefore, providing the antireflection film only at a position where light collected by the microlens enters can prevent a reduction in a quantity of light received, as compared with a case where the antireflection film is provided on an entire surface of the photo-detecting region. Therefore, the solid-state image pick-up device according to the present invention can attain high sensitivity, low dark output, and a high S/N ratio.

In addition, if the area of the antireflection film is equal to or greater than 70% of the surface area of the photo-detecting region, a fluctuation in sensitivity among pixels, which may occur when the solid-state image pick-up device is used for a camera with interchangeable lenses, can be suppressed, thus realizing high image quality.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1A is a top view of a solid-state image pick-up device according to an embodiment of the present invention;

FIG. 1B is a cross-sectional view along a line A-B in FIG. 1A;

FIG. 2 is a diagram showing a relationship of a distance of a clearance S1 between an antireflection film and an element isolation region and dark output;

FIG. 3 is a diagram showing a relationship of a distance of a clearance S2 between the antireflection film and a gate electrode and the dark output;

FIG. 4 is a diagram illustrating a difference of incidence angles of light passing through a camera lens, depending on pixel positions;

FIG. 5 is a top view of a chip of the solid-state image pick-up device;

FIG. 6 is a diagram illustrating differences, depending on camera lenses, of incidence angles of light entering into a corner pixel;

FIG. 7 is a diagram showing a relationship between a ratio of an area of a photo-detecting section to an area of the antireflection film and a ratio of sensitivity of a pixel at a central position to sensitivity of a pixel at a position in the inner periphery and most distant from the center;

FIG. 8A is a top view of a conventional solid-state image pick-up device;

FIG. 8B is a cross-sectional view along a line A-B of the conventional solid-state image pick-up device shown in FIG. 8A;

FIG. 9 is a diagram illustrating an example of a circuit of a pixel section; and

FIG. 10 is a sectional view of another conventional solid-state image pick-up device.

### DESCRIPTION OF THE PREFERRED EMBODIMENTS

### First Embodiment

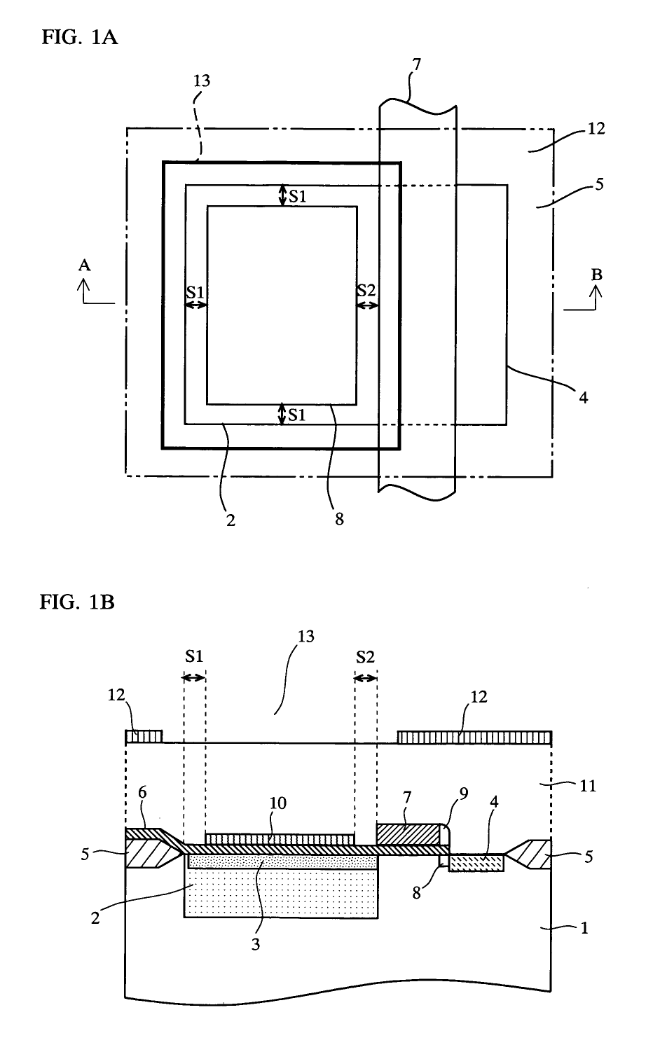

FIG. 1A and FIG. 1B show a top view and a cross-sectional view along a line A-B in FIG. 1A, of a pixel section in a MOS solid-state image pick-up device according to a first embodiment of the present invention. The pixel section, within a semiconductor substrate 1 which is a P-type silicon substrate, comprises an N⁻-type photo-detecting section 2, a P⁺⁺-type surface layer 3, an N⁺-type drain region 4, an isolation region 5, and an N-type LDD (Light Doped Drain) section 8. On a surface of the semiconductor substrate 1, an insulating film 6 which is a silicon oxide film is formed. On the insulating film 6, an antireflection film 10, a gate electrode 7, a side wall 9 of a silicon oxide, an interlayer dielectric film 11, a light-shielding film 12 and the like are formed. An area of the antireflection film 10 is smaller than a surface area of the photo-detecting section 2. An area enclosed by a thick line shown in FIG. 1A is an opening of the light-shielding film 12. An area of the opening of the light-shielding film 12 is larger than the surface area of the photo-detecting section 2.

In the solid-state image pick-up device, the transfer transistor comprises a part of the photo-detecting section 2, a part of the semiconductor substrate 1, the drain region 4, and the gate electrode 7. An electric charge accumulated in the photo-detecting section 2 runs through a channel which appears on a surface of the semiconductor substrate 1 upon an application of a predetermined voltage to the gate electrode 7 and is transferred to the drain region 4. In the drain region 4, the transferred electric charge is temporarily accumulated. Though not shown, an interlayer dielectric film, a color filter, a microlens and the like are formed on the light-shielding film 12.

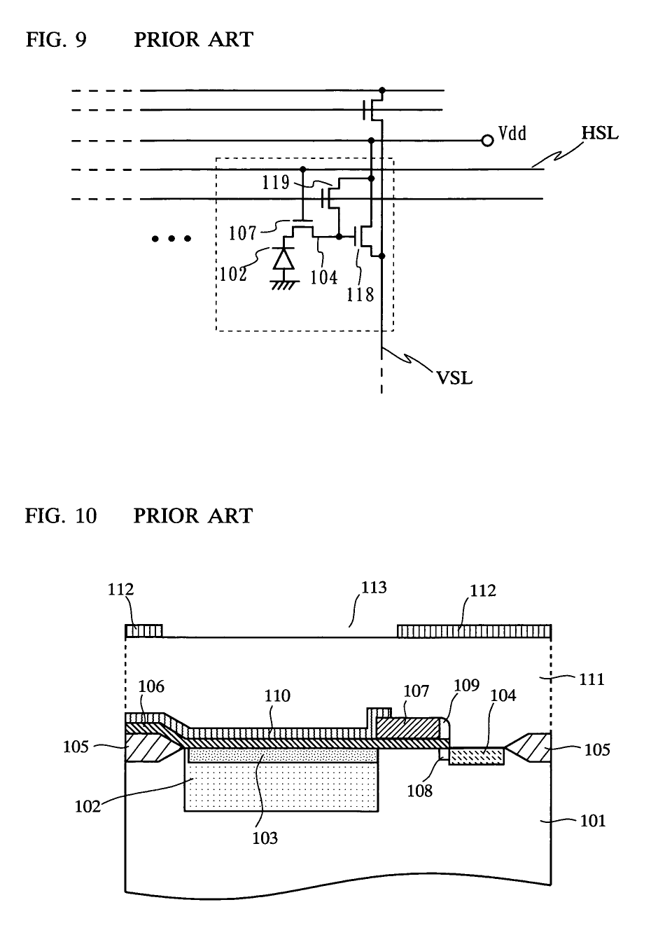

In addition to the transfer transistor comprising the part of the photo-detecting section 2, the part of the semiconductor substrate 1, the drain region 4, and the gate electrode 7, the pixel section comprises readout circuits such as an amplifying transistor and a reset transistor (see FIG. 9). A voltage in accordance with a quantity of the electric charge retained by the drain region 4 is applied to a gate of the amplifying transistor and the amplifying transistor outputs to a vertical signal line VSL a signal amplified with an amplification degree in accordance with a magnitude of the voltage applied to the gate. The signal appearing on the vertical signal line VSL is read out to a final output section and outputted externally. In the amplifying transistor, a source electrode thereof is connected to GND via a load MOS transistor and a load resistor, forming a source follower circuit. The reset transistor is provided to discharge to a power source the signal electric charge retained by the drain region 4 periodically at a given interval.

Here, impurity concentrations of respective sections will be described. The photo-detecting section 2 is formed so as to perform photoelectric conversion and an impurity concentration thereof is preferably approximately 10¹⁵ to 10¹⁶ cm⁻³. A depth of the photo-detecting section 2 (a diffusion depth of N-type impurity) is preferably approximately 0.5 to 2.0 μm. As shown in FIG. 1B, providing a buried-type photodiode having a shallow P-type impurity layer (a surface layer 103) formed on a surface of the photo-detecting section 2 enables a reduction in dark output. However, the surface layer 3 is not an essential component in the solid-state image pick-up device according to the present invention.

An impurity concentration of the drain region 4, which allows an ohmic connection with a metal wire, is preferably equal to or greater than 10²⁰ cm⁻³. As a depth of the drain region 4 (a diffusion depth of N-type impurity), approximately 0.2 to 0.4 μm is appropriate. An LLD section 8 has a lower impurity concentration than the drain region 4 and an N-type impurity concentration thereof, for example, of 10¹⁸ to 10¹⁹ cm⁻³ is appropriate.

A material of the antireflection film 10 whose refractive index is between refractive indices of the semiconductor substrate 1 and the insulating film 6 and which can be film-formed is used. If the semiconductor substrate 1 is a silicon substrate having a refractive index of approximately 3.49 and the insulating film 6 is a silicon oxide film having a refractive index of approximately 1.46, appropriate materials for the antireflection film 10 are a silicon oxide, silicon oxide nitride, a cerium oxide, a titanium oxide, a tantalum oxide, a zirconium oxide or a mixture of the above-mentioned materials. Among these materials, in particular, a material containing the silicon nitride is suitable. A material for the light-shielding film 12 is, as long as the material has light-shielding effect, not limited to a specific material, and aluminum, tungusten, and silicide are generally used.

The antireflection film 10 may be of a single-layer structure or a multi-layer structure. In a case of the multi-layer structure, a plurality of kinds of films in which the above-mentioned materials are used may be laminated or these films and a silicon oxide film may be laminated. Since a wavelength which enables antireflection varies depending on a material and a film thickness of the antireflection film 10, the film thickness of the antireflection film is not limited to a uniform thickness. For example, if the insulating film 6 is a silicon oxide film and the antireflection film 10 is a silicon nitride film, the insulating film 6 having a thickness of 10 to 30 nm and the antireflection film 10 having a thickness of 40 to 60 nm enables reflection of a wave length of 550 nm to be suppressed in a most effective manner.

As described above, the solid-state image pick-up device according to the present invention comprises the antireflection film 10, on the photo-detecting section 2, whose surface area is smaller than that of the photo-detecting section 2. The antireflection film 10 is formed on a central portion of the photo-detecting section 2 and not formed on boundaries between the photo-detecting section 2 and a periphery thereof.

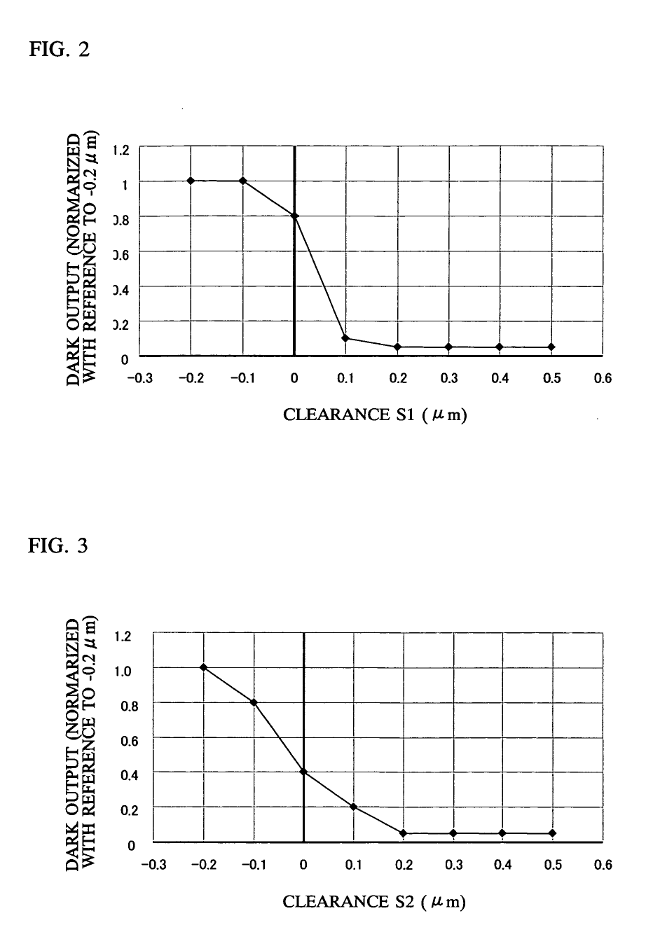

FIG. 2 shows a relationship between a dark output and a distance of a clearance S1 (μm), shown in FIG. 1A and FIG. 1B, between the antireflection film 10 and an isolation region 5. When the distance of the clearance S1 is equal to or greater than 0.2 μm, the dark output can be suppressed, reaching 5% or less of dark output resulting when the antireflection film 10 is formed on the isolation region 5 (see FIG. 10). Judging from this result, 0.2 μm or more of the distance of the clearance S1 is preferable.

Similarly, FIG. 3 shows a relationship between dark output and a distance of a clearance S2 (μm) between the antireflection film 10 and the gate electrode 7. If the distance of the clearance S2 is equal to or greater than 0.2 μm, the dark output can be suppressed, reaching 5% or less of dark output resulting when the antireflection film 10 is formed also on the gate electrode 7. Judging from this result, 0.2 μm or more of the distance of the clearance S2 is preferable.

Conventionally, it had been considered that forming the antireflection film 10 so as to cover an entire surface of the photo-detecting section 2 would enable suppressing reflection, on the surface of the photo-detecting section 2, of light entered from an opening 13 in a most effective manner (see FIG. 10). Therefore, the antireflection film 10 having a larger area than that of the opening 13 had been provided. And it had been considered that providing the above-mentioned antireflection film 10 would increase a quantity of received light and thereby lead to improving a S/N ratio.

However, the inventors of the present invention found out that if the antireflection film 10 is formed so as to cover the entire surface of the photo-detecting section 2, a stress caused through forming the antireflection film 10 increases surface defects, on the semiconductor substrate 1, around boundaries between the photo-detecting section 2 and the isolation region 5 and around boundaries between the photo-detecting section 2 and the gate electrode 7, thereby increasing the dark output. Specifically, if the surface defects increases, free electrons in the surface defects flow into the photo-detecting section 2 as dark electrons, resulting in an increase in the dark output.

Therefore, in the solid-state image pick-up device according to the present invention, the antireflection film 10 is formed so as to have a smaller area than a surface area of the photo-detecting section 2 by avoiding formation of the antireflection film 10 on areas around boundaries between the photo-detecting section 2 and the gate electrode 10 and areas around boundaries between the photo-detecting section 2 and the isolation region 5. Forming the antireflection film 10 in the above-mentioned manner allows an increase in a number of the surface defects to be prevented and thereby an increase in the dark output to be suppressed.

In general a microlens is provided above the photo-detecting section 2 and light collected by the microlens enters the photo-detecting section 2 in a pinpointed manner. Therefore, if the antireflection film 10 is provided only on a position where the light collected by the microlens enters, the quantity of light received is not reduced as compared with a case where the antireflection film 10 is provided on the entire surface of the photo-detecting section 2. Thus, the solid-state image pick-up device with high sensitivity, low dark output, and a high S/N ratio is realized.

Although in the present embodiment the semiconductor substrate 1 is the P-type substrate, the semiconductor substrate 1 may be an N-type substrate in which an N-type photo-detecting section 2 and an N-type drain region 4 are included in a P-type well having a P-type impurity implanted.

The solid-state image pick-up device according to the present invention is a MOS solid-state image pick-up device having the transfer transistor therein, and may be active-type comprising an amplifying transistor in a readout circuit in each pixel section and may be passive-type comprising no amplifying transistor.

### Second Embodiment

A solid-state image pick-up device according to a second embodiment of the present invention, which comprises an antireflection film 10 having a size suited for use in a camera with interchangeable lenses will be described. The solid-state image pick-up device according to the present embodiment is of a same structure as that of the solid-state image pick-up device which is described in the first embodiment and shown in FIG. 1A and FIG. 1B. The solid-state image pick-up device of the second embodiment is different from the solid-state image pick-up device of the first embodiment in that an area of the antireflection film 10 is equal to or greater than 70% of a surface area of a photo-detecting section 2.

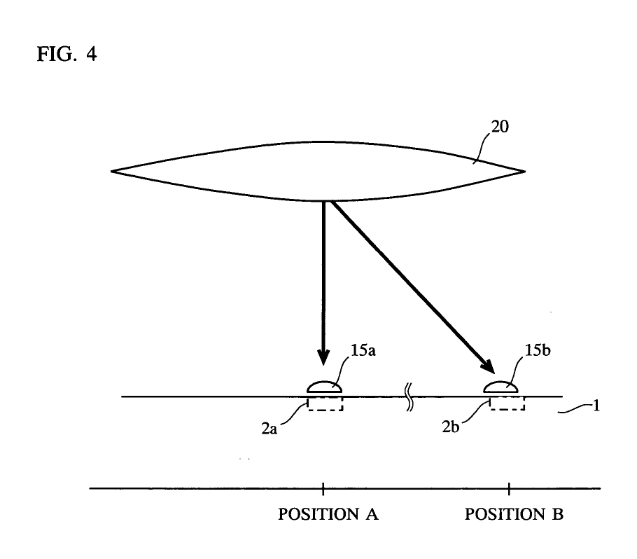

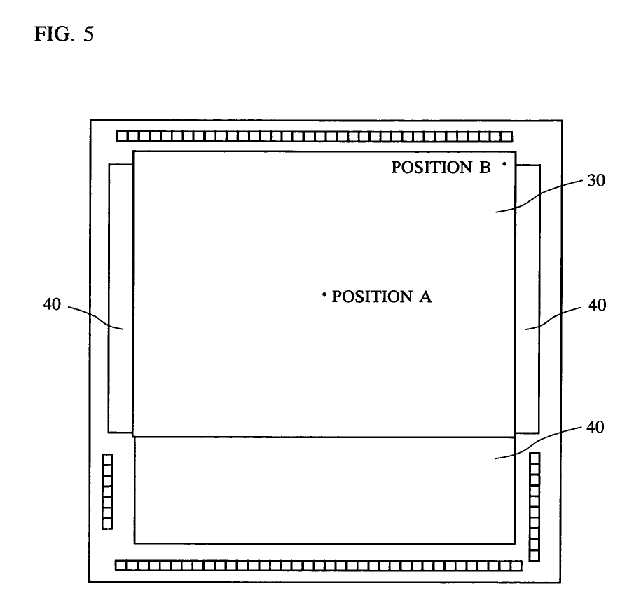

FIG. 4 is a diagram illustrating a pixel section which comprises microlenses 15a and 15b and photo-detecting sections 2a and 2b, and a camera lens 20. In FIG. 4, pixel sections at positions A and B are, among pixel sections which are disposed in a matrix manner in a pixel region 30 of a chip shown in FIG. 5, disposed respectively at a position around a central portion and a position, which is most distant from a center, in an inner periphery. Peripheral circuitry regions 40 where peripheral circuits of the pixel section (a vertical scanning circuit, a horizontal scanning circuit, etc.) are provided are outer peripheral regions surrounding the pixel region 30 in FIG. 5. As indicated by a thick-lined arrow in FIG. 4, an incident angle of light entered through the camera lens 20 into each pixel section varies depending on a position at which a pixel section is disposed. More specifically, a tilt angle of incident light to a central axis of the microlens increases as the position of the microlens approaches from the central portion to the periphery.

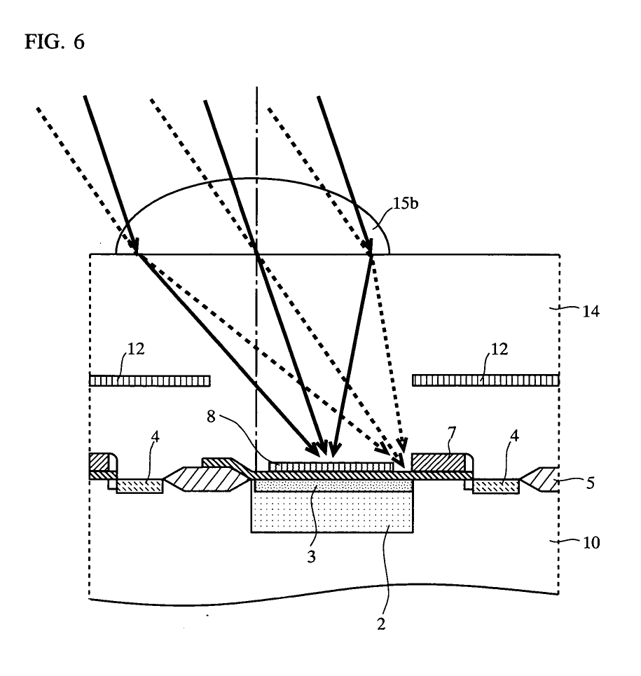

In a camera having interchangeable lenses, replacement of the camera lens 20 is made in accordance with a purpose. Influence of replacing the camera lens 20 is more apparent, particularly in a pixel which is in the inner periphery and most distant from the central portion. FIG. 6 shows the pixel section at the position B shown in FIG. 5. In FIG. 6, thick continuous lines show directions of incident light entering into the microlens 15b when a first camera lens is equipped on a camera body, and dotted lines show directions of incident light entering into the microlens 15b when a second camera lens, which is different from the first camera lens, is equipped on the camera body.

In FIG. 6, incident light passing through the first camera lens is collected to the central portion of the photo-detecting section 2 by the microlens 15b. Because the antireflection film 10 is provided on the central portion of a surface of the photo-detecting section 2, if the first camera lens is used, a quantity of received light increases as compared with a case where the antireflection film 10 is not provided.

On the other hand, if the second camera lens is used, light passing through the second camera lens is collected to a portion along a boundary between the photo-detecting section 2 and a periphery thereof. If the antireflection film 8 is not provided on the portion along the boundary between the photo-detecting section 2 and the periphery thereof, a quantity of light entering when the second camera lens is used is substantially same as that entering when the second camera is used in a case where the antireflection film 10 is not provided, and becomes smaller than that entering when the first camera lens is used.

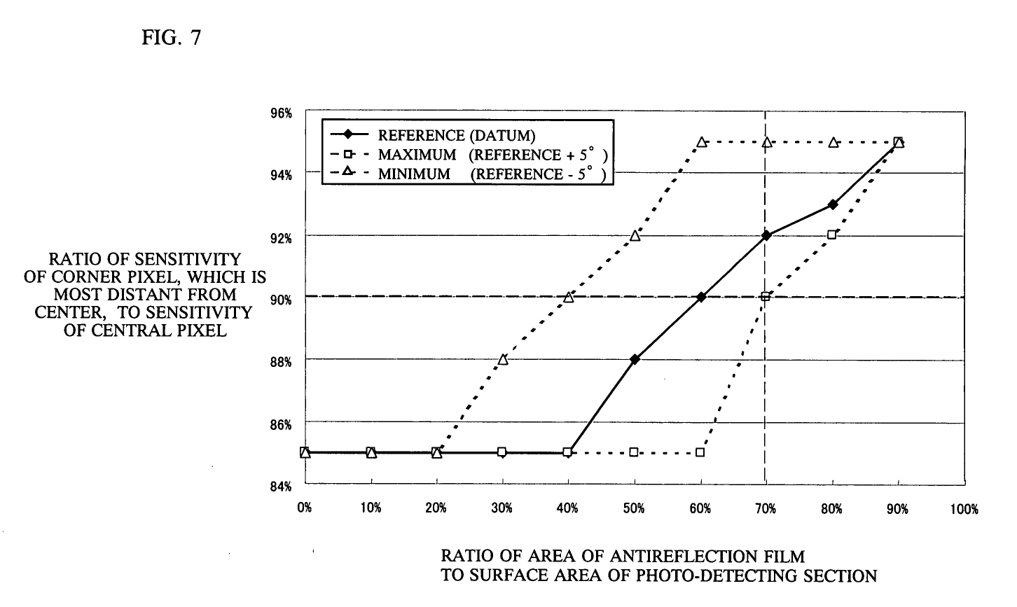

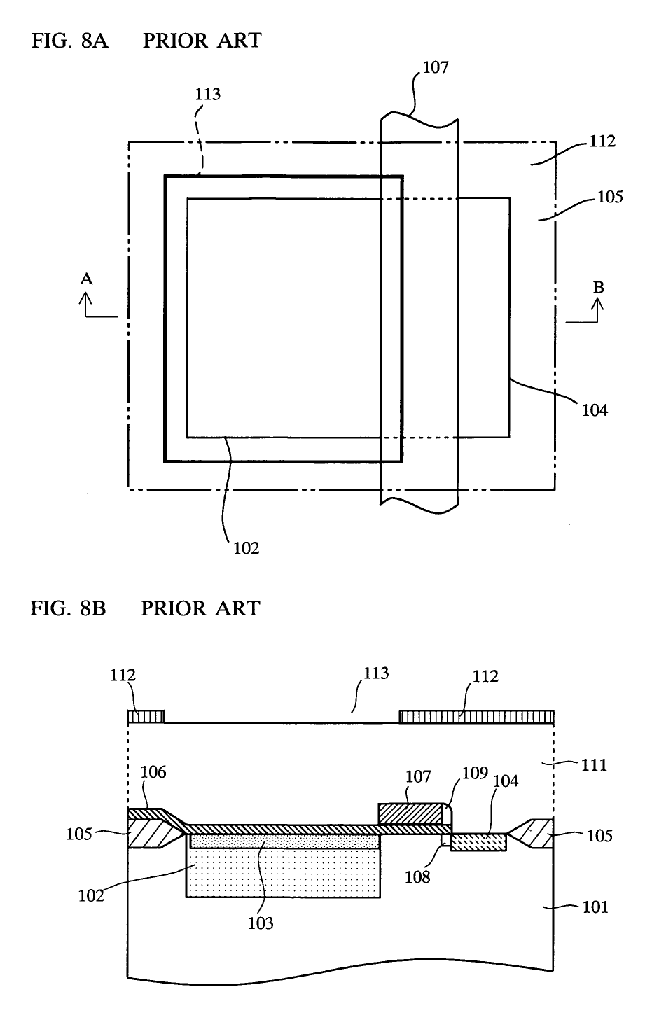

For a general lens-interchangeable type single-lens reflex camera, various kinds of camera lenses are utilized. In general, a datum angle of incident light is set within a range of 2° to 8°. An angle of incident light, with reference to the datum angle, entering into a corner pixel which is most distant from the center depends on a kind of a camera lens. The angle of the incident light is increased by up to 5° and decreased by up to 5°. In general, the quantity of received light of the pixel at the position B is required to be equal to or greater than 90% of the quantity of received light of the pixel at the position A. FIG. 7 shows a result of the experiment for exploring a size of the antireflection film 10, which can satisfy this requirement. In FIG. 7, a vertical axis shows a sensitivity ratio of the corner pixel (pixel section at the position B), which is most distant from the center of the pixel region, to the pixel (pixel section at the position A) around the central portion. And a horizontal axis shows an area ratio of the antireflection film to the surface of the photo-detecting section 2. In FIG. 7, a continued line shows a relationship between a ratio of an area of the antireflection film to an area of the surface of the photo-detecting section and a ratio of sensitivity of the pixel at the central position to sensitivity of the pixel at the position in the inner periphery, which is most distant from the center, accruing when an angle of incident light entering to the pixel at the position B is a reference (datum) angle. And a dotted line shows a relationship between a ratio of an area of the antireflection film to a surface area of the photo-detecting section and a ratio of sensitivity of the pixel at the central position to sensitivity of the pixel at the position in the inner periphery, which is most distant from the center, accruing when an angle of incident light entering to the pixel at the position B is increased by 5° from the reference angle and decreased by 5° from the reference angle.

This experimental result shows that when the area of the antireflection film 10 is equal to or greater than 70% of the surface area of the photo-detecting section 2, 90% or more of a ratio of sensitivity of the pixel section at the position B to sensitivity of the pixel section at the position A is achieved. The solid-state image pick-up device according to the present embodiment satisfies this condition, thus suppressing a fluctuation in sensitivity among pixels and attaining high picture quality.

The solid-state image pick-up device according to the present invention is useful for a camera which is required to achieve a high S/N ratio and high image quality even at low illuminance, for example, a high-class single-lens reflex type digital still camera; for a solid-state image pick-up device for a digital still camera for consumer and professional use; and for a solid-state image pick-up device, used for mainly imaging high-definition moving picture, for use in broadcasting.

While the invention has been described in detail, the foregoing description is in all aspects illustrative and not restrictive. It is understood that numerous other modifications and variations can be devised without departing from the scope of the invention.

What is claimed is:

1. A solid-state image pick-up device comprising:
a plurality of pixels arranged on a semiconductor substrate, each of the pixels each including a photo-detecting section for accumulating an electric charge in accordance with a quantity of light received;
a plurality of antireflection films, each having an area smaller than a surface area of the photo-detecting section and formed on each of the photo-detecting sections; and
an interlayer dielectric film having a plurality of openings, each having an area equal to or greater than the surface area of the photo-detecting section, which are formed above the antireflection film.

2. The solid-state image pick-up device, according to claim 1, further comprising an isolation region for isolating the pixels from each other, wherein
a clearance between the isolation region and the antireflection film is equal to or greater than 0.2 μm.

3. The solid-state image pick-up device, according to claim 1, further comprising a plurality of transfer transistors, the transfer transistors each being adjacent to the photo-detecting section, wherein
a clearance between the gate electrode of the transfer transistor and the antireflection film is equal to or greater than 0.2 μm.

4. The MOS solid-state image pick-up device according to claim 1, wherein an area of the antireflection film is equal to or greater than 70% of the surface area of the photo-detecting section.
